(19) United States
(12) Patent Application Publication
(10) Pub. No.: US 2005/0081788 A1
(43) Pub. Date: Apr. 21, 2005

(54) Device for depositing thin layers on a substrate

(76) Inventors: Holger Jurgensen, Aachen (DE); Gerhard Karl Strauch, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/941,155

(22) Filed: Sep. 15, 2004

Related U.S. Application Data
(63) Continuation of application No. PCT/EP03/02608, filed on Mar. 13, 2003.

(30) Foreign Application Priority Data
Mar. 15, 2002 (DE) 102 11 442.0

(51) Int. Cl. C23C 16/00

(52) U.S. Cl. 118/718

(57) ABSTRACT

The invention relates to a device for depositing thin layers on a substrate, comprising a process chamber arranged in a reactor housing, the bottom of said process chamber being formed by a susceptor for receiving at least one substrate and a gas inlet organ being assigned to the lid of said process chamber, wherein the process gas can be introduced into the process chamber by means of a gas outlet surface which is substantially evenly distributed on the surface thereof and which points towards the susceptor. In order to prevent parasitic accumulation in the gas inlet organ, the gas outlet surface is formed by a gas-permeable diffuser plate, which can extend parallel to a gas outlet plate having a plurality of gas outlet holes arranged in the form of sieves.

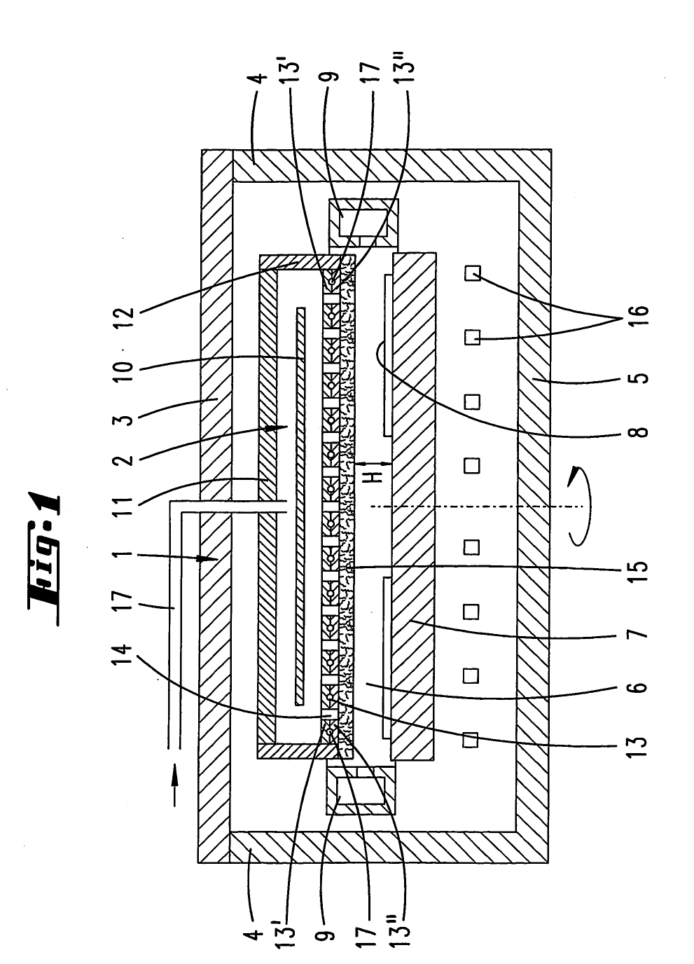

This application is a continuation of pending International Patent Application No. PCT/EP03/02608 filed Mar. 13, 2003 which designates the United States and claims priority of pending German Application No. 102 11 442.0 filed Mar. 15, 2002.

### FIELD OF THE INVENTION

The invention relates to a device for depositing thin films on a substrate, having a process chamber which is disposed in a reactor housing and the base of which is formed by a susceptor for receiving at least one substrate and the cover of which has associated with it a gas inlet member, from which the process gas can be introduced into the process chamber in a substantially uniform areal distribution over its entire gas outlet surface facing toward the susceptor.

A device of this type is known from DE 695 047 62 t2. The aforesaid document describes a device and a process for depositing III-V semiconductors on a substrate which is disposed in a process chamber and is located on a susceptor, which forms the base of a process chamber, the cover of which is formed by a gas inlet member. The gas inlet member has a planar gas outlet surface which extends at a parallel spacing from the surface of the susceptor. The diameter of the susceptor is considerably larger than the clear spacing between the susceptor and the gas outlet surface. To achieve a substantially uniform areal distribution of the process gas emerging from the gas inlet member over its entire gas outlet surface facing toward the susceptor, the gas outlet surface has a multiplicity of openings which open out there and are assigned passages which penetrate through the base plate of the gas inlet member and originate in a gas volume which is fed with the process gas by a gas feed line. This showerhead-like gas feed into the process chamber has the advantage of thereby allowing homogenous growth of the semiconductor layers on the substrates located on the susceptor. The susceptor is inductively heated from below, i.e. from the side remote from the process chamber, by means of a radiofrequency coil. The susceptor can be driven in rotation about its axis.

Journal of Crystal Growth 195 (1998) 725-732 presents considerations concerning what influence the rotational speed of the susceptor and spacing between the susceptor and gas outlet surface, and also the diameter of the susceptor, may have on the film properties. The result of these considerations is that small spacings lead to optimum film properties and to more efficient utilization of the process gases. The best results are predicted for spacings of between 16 and 25 mm.

On account of the openings acting in the manner of nozzles, the process gas is fed into the process chamber in jet form. If the substrate holder is at a sufficient distance from the gas outlet opening, the effect of the individual jets has scarcely any noticeable effect on the film properties. The jets emerging from the gas outlet openings relax above the diffusion boundary layer, where they impinge on one another, so that no influence on the layer homogeneity can arise. Any influences can also be reduced by an increased process chamber pressure. Whereas the susceptor is heated to a relatively high temperature, to avoid premature decomposition of the process gases and parasitic deposits, the gas inlet member has to be cooled. In the prior art, this is effected by water cooling of the base plate of the gas inlet member. However, if the process chamber height is reduced, there is nevertheless the risk of deposits on the gas outlet surfaces in the region between the openings, on account of the increasing temperature gradient in the vertical direction in the process chamber and on account of the diffusion transport mechanisms which are changed as a result. The openings act as nozzles. Flow detachment may occur at the edges of the openings. The detachment behavior depends on the level of the Reynolds number. The prior art has already proposed conical or cone-like openings. Even this is unable to entirely prevent detachment of the flow. The flow detachment has the consequence of producing a space between two nozzles which has little flow passing through it. A dynamic pressure difference with respect to the nozzle jet is produced. Consequently, the concentration of the starting substances may be enriched in this space as a result of diffusion. This enrichment may cause the condensation temperature to be exceeded. This would lead to condensation taking place in the gas phase or at the surface of the gas inlet member. Although increasing the temperature of the gas inlet member prevents condensation, it can lead to local decomposition of the starting substance there, which is undesirable. Parasitic growth may commence as a result. The material deposited there, by flaking off, may have an adverse effect on the CVD process.

The invention is therefore based on the object of providing means for avoiding parasitic deposits on a gas inlet member of the generic type.

The object is achieved by the invention given in the claims, in which it is provided in claim 1 that the gas outlet surface is formed by a gas-permeable diffusor plate. This diffusor plate may extend parallel to a gas outlet plate which includes a multiplicity of gas outlet openings disposed in the form of a sieve. This gas outlet plate may form the base of a chamber of the gas inlet member. The spacing between the susceptor and the gas outlet surface, i.e. the underside of the diffusor plate, is preferably less than 80 mm or 50 mm. This spacing may even be less than 40 mm or less than 30 mm. There is also provision for this spacing to be less than 25 mm, 20 mm, 16 mm or less than 11 mm. The process chamber is surrounded by a gas outlet ring. The gas outlet ring has a multiplicity of openings which are directed onto the center of the circular process chamber and through which the gas can flow out of the process chamber into the hollow interior of the gas outlet ring. The gas outlet ring has one or more discharge lines which lead to a pump, the pump power of which is adjustable, so that the total pressure within the process chamber is adjustable. The diffusor plate may preferably consist of a porous material. The porous material may be formed by a metallic material, a ceramic material or by quartz glass. For example, the diffusor plate may be a solid, open-cell foam. However, the diffusor plate may also be formed by a multilayer woven fabric or a random-laid fabric. It is pertinent that the diffusor plate should widen the gas stream introduced at various positions which are locally separate from one another, so that a homogenous gas curtain flows into the process chamber. For this purpose, the diffusor plate may be disposed in touching contact beneath the gas outlet plate of the gas inlet member. Since the gas outlet plate of the gas inlet member can be cooled, as described, for example, in DE 695 047 62 T2, the diffusor plate is also cooled on account of the touching contact. The spacing of the openings provided in sieve-like form in the gas outlet plate can, on account of this configuration, be made relatively large, so that sufficient space for a volume through which coolant can flow still remains between these openings, which may be formed by small tubes. The spacing of the openings may therefore be greater than a quarter of the spacing between susceptor and gas outlet surface.

The spacing of the openings in the gas outlet plate may even be greater than what is normally required to relax the jets emerging from the openings before they reach the diffusion boundary layer. Although the gas flows into the diffusor plate in jet form from these openings, the gas enters the process chamber at a reduced flow velocity, which is in particular uniform over the entire area of the gas outlet surface. There are no longer scarcely any discrete jets which emerge from the gas inlet member. The material thickness of the diffusor plate may be selected in such a way that its underside, which faces the process chamber, is still at a temperature at which no local decomposition of the starting substances occurs. There is therefore also no limiting growth. The temperature of the diffusor plate surface is typically between 100° C. and 300° C. The porosity and material thickness, and also the conductivity, of the diffusor plate can be matched to the prevailing process parameters, and in particular to the carrier gas.

On account of the diffusor plate, the process chamber height can be reduced to values which are smaller than in a conventional configuration of the gas outlet surface. This is particularly advantageous when depositing semiconductor layers using the MOCVD process, in which the growth is diffusion-limited. The process gas is fed directly into the diffusion zone, specifically in a homogenous manner.

An exemplary embodiment of the invention is explained below with reference to the accompanying drawings.

The reactor housing 1 comprises a housing lower part, which comprises the wall 4 and the base 5, and also a cover part 3, which can be removed for loading of the process chamber 6. A gas inlet member 2 is fixedly mounted on the cover part 3. This gas inlet member 2 is fed by means of a gas feed line 17. The gas inlet member 2 has a hollow chamber into which the gas feed line 17 opens out. This chamber is delimited at the top by a cover plate 11, to the side by a circular ring 12 and toward the process chamber 6 by a gas outlet plate 13. The gas outlet plate may be water-cooled, in the form described in DE 695 047 62 T2. It may also comprise two plates 13′, 13″, between which passages through which coolant can flow are disposed. Inside the chamber of the gas inlet member 2 there may be an intermediate plate 10, which only allows flow to pass around its edge, in order to promote the uniform gas distribution.

Beneath the gas outlet plate 13 there is a diffusor plate 15. The diffusor plate 15 is an additional plate fitted in touching contact beneath the gas outlet plate 13.

A circular susceptor 7, which can be inductively heated from below by means of an RF heater coil 16, is located in a parallel position to the diffusor plate 15 at a spacing H from the gas outlet surface, which is formed by the free surface of the diffusor plate 15. The susceptor 7, which may consist, for example, of quartz, graphite or coated graphite, can rotate about its central axis. It is driven in rotation. One or more substrates 8 can be placed on that surface of the susceptor 7 which faces toward the diffusor plate 15.

The process chamber 6 is surrounded by a gas outlet ring 9. This gas outlet ring has an annular hollow interior which has openings toward the process chamber 6, through which the process gas can flow into the hollow interior of the gas outlet ring 9. At one or more locations, the gas outlet ring 9 has discharge lines, which are not shown in the drawing and lead to a pump (not shown). The pump power is controllable. As a result, a predetermined total gas pressure can be set within the process chamber 6.

The diffusor plate 15 may consist of a porous material. It may, for example, be formed by a quartz frit. However, the diffusor plate may also consist of metal, in particular of stainless steel. Ceramic is also a suitable material. The diffusor plate may take the structure of an open-cell hard foam. However, the diffusor plate may also be a random-laid fabric or a multilayer woven fabric.

A pertinent property of the diffusor plate 15 is that of uniformly introducing the gas, which flows locally through the gas inlet openings 14 out of the gas volume of the gas inlet member 2 and has a high gas velocity, into the process chamber 6. The gas which locally emerges through the openings 14 is passed into the process chamber 6 over a broad area, with the gas velocity being homogenized and reduced, so that the jet action which the gas outlet openings 14 would produce without the diffusor plate is reduced. The zones of low flow velocity, which are disadvantageous in the prior art, next to the jets emerging from the openings, now no longer exist. No increase in concentration occurs there, and therefore there is also no condensation. The temperature on the underside of the diffusor plate is selected in such a way that no local decomposition of the starting substances occurs there. The temperature is preferably between 1000 and 300° C. The material thickness and porosity of the diffusor plate are selected in such a way that the gas “jets” emerging from the individual gas outlet openings 14 widen out.

The diffusor plate 15 is in closely touching contact with the in particular water-cooled gas outlet plate 13. As a result, the diffusor plate 15 is also held at a relatively low temperature, so that a large vertical temperature gradient can be established in the process chamber 6.

The device can be operated at total gas pressures of between 10 mbar and atmospheric pressure. However, there is also provision for the device to be operated at lower pressures. The rotational speed of the susceptor may be between 10 rpm and 1000 rpm. A total gas flow of 8 slm to 50 slm can be introduced into the process chamber, which has a height of preferably 50 mm and a diameter of more than 10, 20 or 30 cm. However, the height of the process chamber may also be less than 50 mm. For example, process chamber heights of 75, 50, 40, 35, 30, 25, 15, 11 or in each case fewer millimeters are possible.

Under certain conditions, it may be necessary for the height H to be limited not just to a maximum but also to a minimum. A minimum limitation of this type is provided for in particular if manufacturing tolerances or the materials properties and the resultant inhomogeneous thermal expansion means that it is impossible to ensure a parallel position between gas outlet surface 15 and substrate holder surface. It is in this case advantageous if the process chamber height is no less than 11 mm.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

1. Device for depositing thin films on a substrate, having a process chamber which is disposed in a reactor housing and the base of which is formed by a susceptor for receiving at least one substrate and the cover of which has associated with it a gas inlet member, on which the process gas can be introduced into the process chamber in a substantially uniform areal distribution over its entire gas outlet surface facing toward the susceptor, characterized in that the gas outlet surface is formed by a gas-permeable diffusor plate.

2. Device according to claim 1, characterized in that the diffusor plate extends parallel to a gas outlet plate which includes a multiplicity of gas outlet openings disposed in the form of a sieve.

3. Device according to claim 1, characterized in that the gas outlet plate forms the base of a chamber of the gas inlet member.

4. Device according to claim 1, characterized in that the spacing (H) between the susceptor and the gas outlet surface is less than 50 mm, less than 40 mm, less than 30 mm, less than 25 mm, less than 16 mm, or less than 11 mm.

5. Device according to claim 1, characterized by a gas outlet ring which annularly surrounds the process chamber.

6. Device according to claim 1, characterized in that the diffusor plate consists of a porous metallic or ceramic material or of quartz glass.

7. Device according to claim 1, characterized in that the diffusor plate is a solid, open-cell foam.

8. Device according to claim 1, characterized in that the diffusor plate is a woven fabric or a random-laid fabric.

9. Device according to claim 1, characterized in that the diffusor plate is disposed in touching contact beneath the in particular water-cooled gas outlet plate.

10. Device according to claim 1, characterized in that the spacing of the openings of the gas outlet plate is greater than half the spacing (H) between susceptor and gas outlet surface of the diffusor plate.

11. Device according to claim 1, characterized in that the thickness of the diffusor plate is 3, 5, 7, 9 or 11 mm.
